(19) United States
(12) Patent Application Publication
(10) Pub. No.: US 2024/0312893 A1
(43) Pub. Date: Sep. 19, 2024

(54) ELECTRONIC DEVICE

(71) Applicant: MEDIATEK INC., Hsinchu City (TW)

(72) Inventors: Hui-Chi TANG, Hsinchu City (TW); Shih-Yi SYU, Hsinchu City (TW); Hao-Ju WANG, Hsinchu City (TW); Pei-San CHEN, Hsinchu City (TW); Duen-Yi HO, Hsinchu City (TW)

(21) Appl. No.: 18/594,446

(22) Filed: Mar. 4, 2024

Related U.S. Application Data
(60) Provisional application No. 63/490,303, filed on Mar. 15, 2023.

(51) Int. Cl. H01L 23/498; H01L 23/00

(52) U.S. Cl. CPC H01L 23/49838; H01L 24/16; H01L 2224/16227; H01L 2924/14361

(57) ABSTRACT

An electronic device is provided. The electronic device includes a base and a semiconductor device. The base has a top surface and a bottom surface. The semiconductor device is disposed on the top surface of the base. The semiconductor device has a device edge located within the base in a top view. The base has a unit pad array which is covered by the semiconductor device and electrically connected to the semiconductor device. The unit pad array includes a first pad region composed of a first row and a second row of the unit pad array. The first pad region includes first pads for transmitting commands and addresses to and from the semiconductor device. The first row of the unit pad array is arranged so that it is closer to the device edge than the second row of the unit pad array.

### CROSS REFERENCE TO RELATED APPLICATIONS

This application claims the benefit of U.S. Provisional Application No. 63/490,303, filed on Mar. 15, 2023, the entirety of which is incorporated by reference herein.

### BACKGROUND OF THE DISCLOSURE

### Field of the Disclosure

The present disclosure relates to an electronic device and, in particular, to the arrangement of a pad array of a base.

### Description of the Related Art

In order to ensure the continued miniaturization and multi-functionality of electronic products and communication devices, it is desired that semiconductor packages be small in size, support multi-pin connection, operate at high speeds, and have high functionality. This will put pressure on semiconductor package fabricators to develop fan-out semiconductor packages.

Although existing semiconductor package assemblies are generally adequate, they are not satisfactory in every respect. For example, it is a challenge to fulfill the pad assignment requirements of the base for matching different structures of dynamic random access memory (DRAM) chips. Therefore, there is a need to further improve semiconductor package assemblies to provide flexibility in pad assignment for base design.

### BRIEF SUMMARY OF THE DISCLOSURE

An embodiment of the present disclosure provides an electronic device. The electronic device includes a base and a semiconductor device. The base has a top surface and a bottom surface. The semiconductor device is disposed on the top surface of the base. The semiconductor device has a device edge located within the base in a top view. The base has a unit pad array which is covered by the semiconductor device and electrically connected to the semiconductor device. The unit pad array includes a first pad region composed of a first row and a second row of the unit pad array. The first pad region includes first pads for transmitting commands and/or addresses to or from the semiconductor device. The first row of the unit pad array is arranged so that it is closer to the device edge than the second row of the unit pad array.

In some embodiments, the unit pad array further includes a second pad region composed of a third row, a fourth row, a fifth row, a sixth row, a seventh row and an eighth row of the unit pad array. The second pad region includes second pads for transmitting data to or from the semiconductor device. In some embodiments, the unit pad array further includes a third pad region composed of a ninth row, a tenth row and an eleventh row of the unit pad array. The third pad region includes third pads for transmitting clocks to or from the semiconductor device. In some embodiments, the unit pad array further includes ground pads arranged in the first pad region, the second pad region and the third pad region except for the first row of the unit pad array.

In some embodiments, the first row of the unit pad array is composed of a portion of the first pads. In some embodiments, the second row of the unit pad array is composed of the remaining first pads and ground pads in the first pad region. In some embodiments, the remaining first pads are alternately arranged with the ground pads in the first pad region. In some embodiments, each of the ground pads in the first pad region is adjacent to the first pads in the first row and the second row of the unit pad array. In some embodiments, the first pads in the second row of the unit pad array are adjacent to the first pads in the first row of the unit pad array.

In some embodiments, the third to the eighth rows of the unit pad array are composed of the second pads and ground pads in the second pad region. In some embodiments, in each of the third to the eighth rows of the unit pad array, the second pads are alternately arranged with the ground pads. In some embodiments, the ground pads in the third row of the unit pad array are adjacent to the second pads and the first pads. In some embodiments, each of the second pads is adjacent to the ground pads in a row direction and a column direction.

In some embodiments, the ninth row to the eleventh row of the unit pad array are composed of the third pads and ground pads in the third pad region. In some embodiments, in the ninth row of the unit pad array, the third pads are alternately arranged with the ground pads. In some embodiments, the third pads in the ninth and eleventh rows are adjacent to the different third pads in the tenth row. In some embodiments, there are five third pads arranged side-by-side in the tenth row of the unit pad array. In some embodiments, the first one, the third one and the fifth one of the third pads in the tenth row are located between the third pads in the ninth row and the ground pads in the eleventh row. In some embodiments, the second and fourth third pads are located between the ground pads in the ninth row and the third pads in the eleventh row.

An embodiment of the present disclosure provides an electronic device. The electronic device includes a base and a semiconductor device. The base has a top surface and a bottom surface. The semiconductor device is disposed on the top surface of the base. The semiconductor device has a device edge located within the base in a top view. The base has a unit pad array which is covered by the semiconductor device and electrically connected to the semiconductor device. The unit pad array includes a first pad region, a second pad region and a third pad region. The first pad region is composed of first pads and a first group of ground pads. The first pads are configured to transmit commands and/or addresses to or from the semiconductor device. The second pad region is composed of second pads and a second group of ground pads. The second pads are configured to transmit data to or from the semiconductor device. The third pad region is composed of third pads and a third group of ground pads. The third pads are configured to transmit clocks to or from the semiconductor device. The first pad region is arranged so that it is closer to the device edge than the second pad region, and the second pad region is arranged so that it is closer to the device edge than the third pad region.

### BRIEF DESCRIPTION OF THE DRAWINGS

The present disclosure can be more fully understood by reading the subsequent detailed description and examples with references made to the accompanying drawings, wherein:

FIG. 1 is a schematic top view of an electronic device in accordance with some embodiments of the disclosure;

FIG. 2 is a schematic cross-sectional view taken along the line A-A′ of the electronic device of FIG. 1 in accordance with some embodiments of the disclosure; and

FIG. 3 is a schematic enlarged view of a distribution area of a pad array of a base of the electronic device of FIG. 1 in accordance with some embodiments of the disclosure, showing the arrangement of the pad array.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

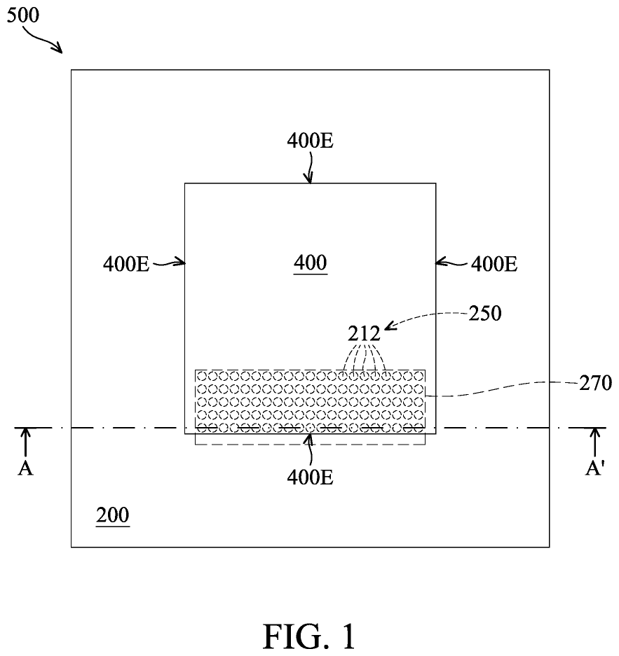

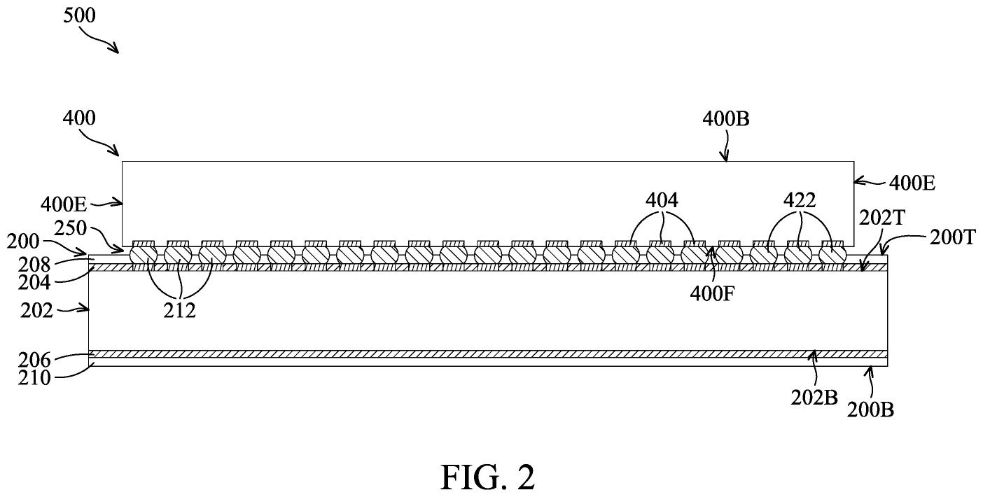

FIG. 1 is a schematic top view of an electronic device 500 in accordance with some embodiments of the disclosure. FIG. 2 is a schematic cross-sectional view taken along the line A-A′ of the electronic device 500 of FIG. 1 in accordance with some embodiments of the disclosure. In some embodiments, the electronic device 500 includes a semiconductor package assembly. The semiconductor package assembly can be used to form a fan-out package, a two-dimensional (2D) package, a 2.5D package, a three-dimensional (3D) semiconductor package, or another suitable package. In some embodiments, the electronic device 500 may include one wafer-level fan-out semiconductor package or more than one vertically stacked wafer-level fan-out semiconductor packages mounted on a base 200. In some embodiments, the electronic device 500 may include one or more semiconductor dies mounted on the base 200. As shown in FIG. 1, in some embodiments, the electronic device 500 includes a base 200 and a semiconductor device 400.

As shown in FIGS. 1 and 2, the base 200, for example a printed circuit board (PCB), a substrate or an interposer, may include an interconnection structure 202, a topmost conductive layer 204, a bottommost conductive layer 206 and solder mask layers 208, 210.

In some embodiments, the interconnection structure 202 may have a top surface 202T and a bottom surface 202B. The top surface 202T of the interconnection structure 202 is close to the semiconductor device 400, while the bottom surface 202B of the interconnection structure 202 is away from the semiconductor device 400. In some embodiments, the topmost conductive layer 204 is formed on the top surface 202T of the interconnection structure 202, and the bottommost conductive layer 206 is formed on the bottom surface 202B of the interconnection structure 202. In some embodiments, the solder mask layer 208 is formed on the topmost conductive layer 204, and the solder mask layer 210 is formed on the bottommost conductive layer 206.

In some embodiments in which the base 200 includes a printed circuit board (PCB), the interconnection structure 202 may serve as a build-up layer structure 202. The build-up layer structure 202 may include a core substrate (not shown) and a plurality of alternating laminated conductive layers (not shown) and dielectric layers (not shown) stacked on opposite sides of the core substrate. In some embodiments, the build-up layer structure 202 may by fabricated without the core substrate and the build-up layer structure 202 may include a plurality of alternating laminated conductive layers (not shown) and dielectric layers (not shown). The top surface 202T is located close to the semiconductor device 400, and the bottom surface 202B is located away from the semiconductor device 400. It is noted that the topmost layer and the bottommost layer of the build-up layer structure 202 are dielectric layers (not shown) in this embodiment. Therefore, the topmost dielectric layer and the bottommost dielectric layers may be exposed from the top surface 202T and the bottom surface 202B of the build-up layer structure 202. In some embodiments, the core substrate may be formed of polypropylene (PP), Pre-preg, FR-4 and/or other epoxy laminate material. In some embodiments, the conductive layer includes a conductive material, such as metals comprising copper, gold, silver, or other applicable metals. In some embodiments, the dielectric layer includes Pre-preg or other applicable dielectric materials.

In some embodiments in which the interconnection structure 202 includes a substrate or an interposer, the interconnection structure 202 may include one or more conductive traces (not shown) and one or more vias (not shown) disposed in one or more dielectric layers. In some embodiments, the conductive traces (not shown) and the vias (not shown) include a conductive material, such as metals comprising copper, gold, silver, or other applicable metals. The dielectric layers (not shown) may include extra-low K (ELK) dielectrics and/or ultra-low K (ULK) dielectric. In addition, the dielectric layers (not shown) may include epoxy.

The topmost conductive layer 204 may be formed on the top surface 202T of the interconnection structure 202. In some embodiments in which the base 200 includes a printed circuit board (PCB), the topmost conductive layer 204 may include a single layer or a multilayer structure. In addition, the topmost conductive layer 204 may include conductive traces (not shown), a pad array 250 including pads 212, and ground planes (not shown) disposed on the base 200. In some embodiments in which the base 200 includes a substrate or an interposer, the topmost conductive layer 204 may include conductive traces (not shown) and the pad array 250 including the pads 212. In some embodiments, the conductive traces may comprise signal trace segments or ground trace segments, which are used for the input/output (I/O) connections of the semiconductor device 400. In some embodiments, the pads 212 are connected to different terminals of the conductive traces. The pads 212 are used for the semiconductor device 400 that is mounted directly on them. In some embodiments, the ground planes are grounded and connected to ground pads of the semiconductor device 400. In some embodiments, the topmost conductive layer 204 includes a conductive material, such as metals comprising copper, gold, silver, or other applicable metals. For example, the topmost conductive layer 204 may be a copper layer 204.

The bottommost conductive layer 206 may be formed on the bottom surface 202B of the interconnection structure 202. In some embodiments, the topmost conductive layer 204 and bottommost conductive layer 206 may include the same or similar materials and structures. For example, the bottommost conductive layer 206 may be a copper layer 206.

The solder mask layer 208 may be disposed on the top surface 202T of the interconnection structure 202 and the solder mask layer 208 may be directly disposed on the topmost conductive layer 204. The solder mask layer 208 may have openings (not shown) to expose pads 212. In some embodiments, the solder mask layer 208 may include an epoxy resin. In some embodiments, a top surface 200T of the solder mask layer 208 close to the semiconductor device 400 may serve as the top surface 200T (which also serves as a chip-attach surface) of the base 200.

The solder mask layer 210 may be disposed on the bottom surface 202B of the interconnection structure 202 and on the bottommost conductive layer 206. In some embodiments, the solder mask layers 208 and 210 may include the same or similar materials. The solder mask layer 208 may have openings (not shown) to expose pads (not shown) connected to conductive traces (not shown) of the bottommost conductive layer 206. In some embodiments, a bottom surface 200B of the solder mask layer 210 located away from the semiconductor device 400 may serve as a bottom surface 200B of the base 200.

The semiconductor device 400 is disposed on the top surface 200T of the base 200. The semiconductor device 400 is mounted on the top surface 200T of the base 200 using conductive structures 422 by a surface mount technology (SMT) process. In some embodiments, the semiconductor device 400 has at least one device edge located within the base 200 in a top view as shown in FIG. 1. For example, the rectangular semiconductor device 400 may have four device edges 400E located within the base 200 in a top view as shown in FIG. 1.

In some embodiments, the semiconductor device 400 may include a semiconductor die or a fan-out semiconductor package. For example, the semiconductor die may include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (IO) die, a dynamic random access memory (DRAM) die (e.g., a double data rate 4 (DDR4) DRAM die, a low-power DDR4 (LPDDR4) DRAM die, a double data rate (DDR) synchronous dynamic random access memory (SDRAM) die or the like), a dynamic random access memory (DRAM) IP core, a static random-access memory (SRAM), a high bandwidth memory (HBM), a dynamic random access memory (DRAM) controller or any combination thereof. The semiconductor package may include a memory package such as a dynamic random access memory (DRAM) package. In some embodiments, the semiconductor device 400 may include more than one vertically stacked semiconductor dies. For example, the semiconductor device 400 may include more than one vertically stacked DRAM dies. In some embodiments, the semiconductor device 400 may include a hybrid package such as a memory package stacked on a system-on-chip (SOC) package.

The semiconductor device 400 may have a back surface 400B and a front surface 400F. The semiconductor device 400 may be fabricated by a flip-chip technology. The back surface 400B of the semiconductor device 400 serve as a top surface 400B of the semiconductor device 400. Pads 404 of the semiconductor device 400 are disposed on the front surface 400F to be electrically connected to the circuitry (not shown) of the semiconductor device 400. In some embodiments, the pads 404 belong to the uppermost metal layer of the interconnection structure (not shown) of the semiconductor device 400. The pads 404 of the semiconductor device 400 are electrically connected to the base 200 using the conductive structures 422.

When the semiconductor device 400 includes a fan-out semiconductor package, the semiconductor device 400 may include at least one semiconductor die (not shown) and a substrate (not shown). The semiconductor die may be disposed on a die-side surface of the substrate located away from the conductive structures 422. The semiconductor die has a back surface away from the conductive structures 422 and a front surface close the conductive structures 422. The semiconductor die may be fabricated by a flip-chip technology. Pads (not shown) of the semiconductor die are disposed on the front surface of the semiconductor die to be electrically connected to the circuitry (not shown) of the semiconductor die. In some embodiments, the pads of the semiconductor die belong to the uppermost metal layer of the interconnection structure (not shown) of the semiconductor die. The pads of the semiconductor die are electrically connected to the substrate using conductive structures (not shown).

The substrate is provided for the semiconductor die to be disposed upon. The substrate is electrically connected to the semiconductor die by the pads of the semiconductor die. In some embodiments, the substrate includes a redistribution layer (RDL) structure having one or more conductive traces (not shown), one or more vias (not shown) disposed in one or more intermetal dielectric (IMD) layers (not shown) and the pads 404. The conductive traces are electrically connected to the corresponding pads 404. The pads 404 are exposed to openings of the solder mask layer (not shown) and close to the base 200. In addition, the conductive structures 422 are disposed on a land-side surface (not shown) of the substrate located away from the semiconductor die. The conductive structures 422 are electrically connected between the pads 404 of the semiconductor device 400 and the pads 212 of the base 200. In some embodiments, the vias, the conductive traces and the pads include a conductive material, such as metals comprising copper, gold, silver, or other applicable metals. The dielectric layers may include extra-low K (ELK) dielectrics and/or ultra-low K (ULK) dielectric. In addition, the dielectric layers may include epoxy.

As shown in FIG. 1, the conductive structures 422 are disposed between the semiconductor device 400 and the base 200. The conductive structures 422 are in contact with the pads 404 of the semiconductor device 400 and the corresponding pads 212 of the base 200. Therefore, the semiconductor device 400 is electrically connected to the base 200 via the conductive structures 422. In some embodiments, the conductive structures 422 include conductive materials, such as metal. The conductive structures 422 may include microbumps, controlled collapse chip connection (C4) bumps, ball grid array (BGA) balls, the like, or a combination thereof. In some embodiments, the conductive structures 422 comprise an under bump metallurgy (UBM) structure (not shown) and a conductive ball structure (not shown) on the UBM structure. The conductive ball structure may include a copper ball, a conductive bump structure such as a copper bump or a solder bump structure, or a conductive pillar structure such as a copper pillar structure. In some embodiments, an underfill (not shown) is introduced into the gap between the semiconductor device 400 and the base 200.

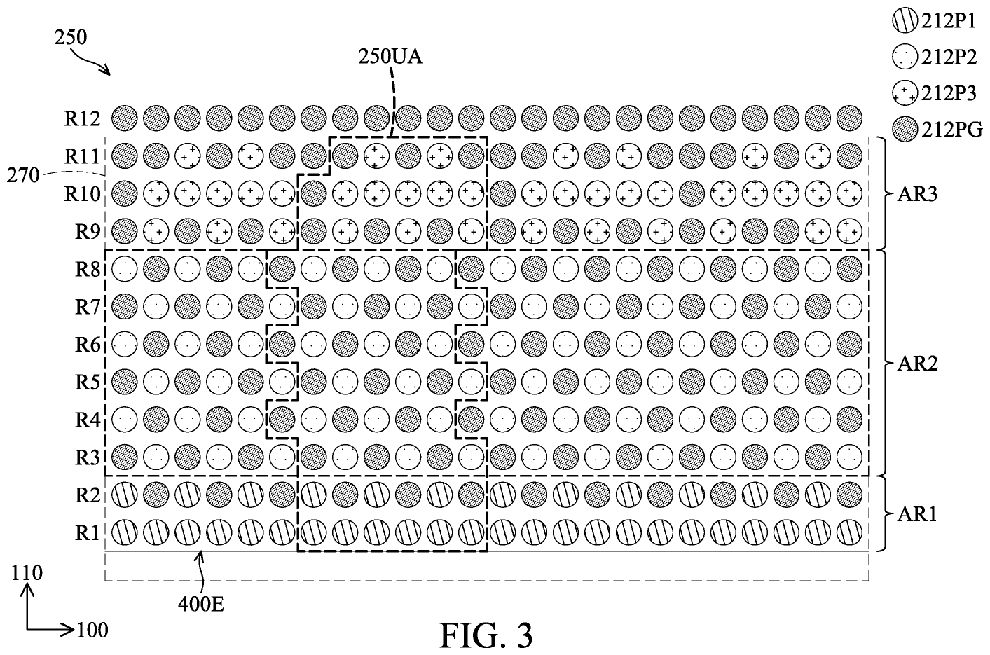

FIG. 3 is a schematic enlarged view of a distribution area 270 of the pad array 250 of the base 200 of the electronic device 500 of FIG. 1 in accordance with some embodiments of the disclosure, showing the arrangement of the pad array 250 including pads 212 (including first pads 212P1, second pads 212P2, third pads 212P3 and ground pads 212PG). As shown in FIG. 3, the pad array 250 of the base 200 is completely covered by the semiconductor device 400. In addition, the pad array 250 of the base 200 is electrically connected to the semiconductor device 400. In addition, the pad array 250 of the base 200 is close to the corresponding device edge 400E of the semiconductor device 400. It is noted that the number and the arrangement of the pads 212 of the pad array 250, the pads 404 of the semiconductor device 400 and the conductive structures 422 of FIGS. 1 and 2 is merely an example. The details of the number and the arrangement of the pads 212 of the pad array 250 are described in the following with FIG. 3.

In this embodiment, a direction 100 is substantially parallel to the device edge 400E of the semiconductor device 400. The direction 100 may be also defined as a row direction 100 of the pad array 250. In addition, a direction 110 is substantially vertical to the device edge 400E of the semiconductor device 400. The direction 110 may be also defined as a column direction 100 of the pad array 250.

In some embodiments, the pad array 250 includes a plurality of unit pad arrays 250UA periodically arranged along the direction 100. The number of the unit pad arrays 250UA can be adjusted according to design requirements of the products, and are not limited to the disclosed embodiments. Each of unit pad arrays 250UA may provide one particular data channel for the conductive structures 422. Each of the unit pad arrays 250UA may have eleven rows (including rows R1, R2, R3, R4, R5, R6, R7, R8, R9, R10 and R11) of pad 212 (FIG. 1). As shown in FIG. 3, in the rows R1 to R11 of the unit pad arrays 250UA, the row R1 is closest to the to the corresponding device edge 400E, and the row R11 is the farthest to the to the corresponding device edge 400E. The rows R1 to R11 may be sequentially and continuously arranged from the corresponding device edge 400E to the central region of the of the semiconductor device 400 along the direction 110.

As shown in FIG. 3, each of the unit pad arrays 250UA includes first pad region AR1, a second pad region AR2 and a third pad region AR3. The first pad region AR1, the second pad region AR2 and the third pad region AR3 are arranged side-by-side along the direction 110 and extend along the direction 100. In some embodiments, the first pad region AR1 is arranged so that it is closer to the corresponding device edge 400E than the second pad region AR2 along the direction 110. In addition, the second pad region AR2 is arranged so that it is closer to the corresponding device edge 400E than the third pad region AR3. In some embodiments, the first pad region AR1 is composed of the row R1 and the row R2 of the unit pad arrays 250UA. The second pad region AR2 is composed of the row R3, the row R4, the row R5, the row R6, the row R7 and the row R8 of the unit pad arrays 250UA. In addition, the third pad region AR3 is composed of the row R9, the row R10 and the row R11 of the unit pad arrays 250UA.

In some embodiments, the first pad region AR1 of the unit pad array 250UA includes first pads 212P1 (also called CA pads 212P1) for transmitting commands and/or addresses to or from the semiconductor device 400. The second pad region AR2 of the unit pad array 250UA includes second pads 212P2 (also called DQ pads 212P2) for transmitting data to or from the semiconductor device 400. The third pad region AR3 of the unit pad array 250UA includes third pads 212P3 (also called CLK pads 212P3) for transmitting clocks to or from the semiconductor device 400. In some embodiments, the unit pad arrays 250UA further includes ground pads 212GP (also called GND pads 212GP) for grounding of the semiconductor device 400. The ground pads 212GP are arranged in the first pad region AR1, the second pad region AR2 and the third pad region AR3 except for the row R1 of the unit pad array 250UA.

In some embodiments, the first pads 212P1, the second pads 212P2, the third pads 212P3 and the ground pads 212GP may be directly (physically and electrically) connected to the conductive structures 422. In some embodiments, the first pads 212P1, the second pads 212P2, the third pads 212P3 and the ground pads 212GP may be electrically connected to the conductive structures 422 by the conductive traces (not shown) of the base 200.

In some embodiments, the first pad region AR1 of the unit pad array 250UA is merely composed of the first pads 212P1 and a first group of the ground pads 212PG (i.e., the ground pads 212GP arranged in the first pad region AR1). The second pad region AR2 of the unit pad arrays 250UA is merely composed of the second pads 212P2 and a second group of the ground pads 212PG (i.e., the ground pads 212GP arranged in the second pad region AR2). The third pad region AR3 of the unit pad arrays 250UA is merely composed of the third pads 212P3 and a third group of the ground pads 212PG (i.e., the ground pads 212GP arranged in the third pad region AR3).

In other words, the first pads 212P1 are arranged in the first pad region AR1 only. The second pads 212P2 are arranged in the second pad region AR2 only. In addition, the third pads 212P3 are arranged in the third pad region AR3 only.

In the first pad region AR1 of the unit pad array 250UA, the rows R1 and R2 have the same numbers of pads 212 and the same pitch. In addition, the pad number of the rows R1 and R2 is six. The first pads of the rows R1 and R2 are CA pads (the first pad 212P1) for transmitting commands and/or addresses to or from the semiconductor device 400. Moreover, the first CA pads of the rows R1 and R2 are aligned each other along the direction 110 (i.e., the column direction 110).

As shown in FIG. 3, the row R1 is composed of the first pads 212P1 arranged side-by-side. The row R1 is composed of the first pads 212P1 only. That is to say, the row R1 does not include any ground pads 212PG or other pads (e.g., the second pads 212P2 or the third pads 212P3) arranged with the first pads 212P1. For example, the row R1 is composed of six first pads 212P1.

In the first pad region AR1 of the unit pad array 250UA, the second row R2 of the unit pad array 250 is composed of the remaining first pads 212P1 and the ground pads 212PG in the first pad region AR1. In some embodiments as shown in FIG. 3, the first pad region AR1 of the unit pad arrays 250UA is composed of nine first pads 212P1 and three ground pads 212PG, the second row of the unit pad array is composed of three first pads 212P1 and three ground pads 212PG. That is to say, the ground pads 212PG in the first pad region AR1 are arranged in the row R2 only. In some embodiments, the first pads 212P1 are alternately arranged with the ground pads 212PG in the first pad region AR1. For example, the three first pads 212P1 are alternately arranged with the three ground pads 212PG in second row R2 of the unit pad array 250.

In some embodiments, each of the ground pads 212PG in the first pad region AR1 is adjacent to the first pads 212P1 in the row R1 and the row R2 of the unit pad array 250UA. For example, in the first pad region AR1, each of the ground pads 212PG is adjacent to one first pad 212P1 in the row R1 along the direction 110 (i.e., the column direction 110) and two first pads 212P1 in the row R2 along the direction 100 (i.e., the row direction 100). In the first pad region AR1 of the unit pad array 250UA, the first pads 212P1 in the row R2 are adjacent to the first pads 212P1 in the row R1 along the direction 110 (i.e., the column direction 110).

In the second pad region AR2 of the unit pad array 250UA, the rows R3, R4, R5, R6, R7 and R8 have the same numbers of pads 212 and the same pitch. For example, the pad number of the rows R3, R4, R5, R6, R7 and R8 is seven, which is the greater than the pad number of the rows R1 and R2. As shown in FIG. 3, in each of the rows R3, R4, R5, R6, R7 and R8 of the unit pad array 250UA, the second pads 212P2 are alternately arranged with the ground pads 212PG. In addition, the first pads of the rows R3, R4, R5, R6, R7 and R8 (i.e., the left-most pads of the rows R3, R4, R5, R6, R7 and R8) are GND pads (the ground pads 212PG) for grounding. The last pads of the rows R3, R4, R5, R6, R7 and R8 (i.e., the right-most pads of the rows R3, R4, R5, R6, R7 and R8) are DQ pads (the ground pads 212PG) for transmitting data to or from the semiconductor device 400. Therefore, each of the rows R3, R4, R5, R6, R7 and R8 is composed of three DQ pads (the second pads 212P2) and three ground pads (the ground pads 212PG).

In the second pad region AR2 of the unit pad array 250UA, the rows R3, R4, R5, R6, R7 and R8 have staggered arrangement along the direction 110 (i.e., the column direction 110). For example, the rows R4, R6 and R8 may offset form the rows R3, R5 and R7 by one pitch in the negative direction 100. For example, in the direction 110, the first GND pads (the ground pads 212PG) of the rows R3, R5 and R7 are aligned to the first CA pad (the first pad 212P1) of the row R2. In addition, the first GND pads (the ground pads 212PG) of the rows R3, R5 and R7 are aligned to the first DQ pads (the second pads 212P2) of the rows R4, R6 and R8. The first GND pads (the ground pads 212PG) of the rows R4, R6, R7 and R8 are aligned each other and located upper-left to the first GND pads (the ground pads 212PG) of the rows R3, R5 and R7. The first DQ pads (the second pads 212P2) of the rows R3, R5 and R7 are aligned to the first GND pad (the ground pad 212PG) of the row R2. In addition, the first DQ pads (the second pads 212P2) of the rows R3, R5 and R7 are aligned to the second GND pads (the ground pads 212PG) of the rows R4, R6 and R8.

In some embodiments, the ground pads 212PG in the row R3 of the unit pad array 250UA are adjacent to the second pads 212P2 in the rows R3 and R4 and the first pads 212P1 in the row R2. The ground pads 212PG in the rows R5 and R7 of the unit pad array are adjacent to the second pads 212P2 in the rows R4, R5, R6, R7 and R8. In some embodiments, each of the second pads 212P2 is adjacent to the ground pads 212PG in the row direction (i.e., the direction 100) and the column direction (i.e., the direction 110).

In the third pad region AR3 of the unit pad arrays 250UA, the rows R9 and R10 have the same numbers of pads 212 and the same pitch. For example, the pad number of the rows R9 and R10 is six, which is the same as the pad number of the rows R1 and R2. The row R11 is one pad less than the rows R9 and R10. For example, the pad number of the row R11 is five.

In the row R9 of the unit pad array 250UA, the first pad is GND pad (the ground pad 212PG) for grounding. In addition, the third pads 212P3 are alternately arranged with the ground pads 212PG. Therefore, the row R9 is composed of three CLK pads (the third pads 212P3) and three ground pads (the ground pads 212PG).

In the row R10 of the unit pad array 250UA, the first pad is GND pad (the ground pad 212PG) for grounding. In addition, the second to sixth pads are CLK pads (the third pads 212P3). That is to say, there are five CLK pads (the third pads 212P3) arranged side-by-side in the row R10 of the unit pad array 250UA. Therefore, the row R10 is composed of five CLK pads (the third pads 212P3) and one ground pad (the ground pad 212PG).

In the row R11 of the unit pad array 250UA, the first, third and fifth pads are GND pad (the ground pad 212PG) for grounding. In addition, the second and fourth pads are CLK pads (the third pads 212P3). In addition, the third pads 212P3 are alternately arranged with the ground pads 212PG. Therefore, the row R11 is composed of two CLK pads (the third pads 212P3) and three ground pads (the ground pads 212PG). The first GND pad (the ground pad 212PG) of the row R11 is located upper-right to the first GND pad (the ground pad 212PG) of the row R10. In some embodiments, the first GND pads (the ground pads 212PG) of the rows R9 and R10 are aligned to the first CA pads (the first pads 212P1) in the rows R1 and R2. The first GND pad (the ground pad 212PG) of the row R11 is aligned to the first GND pad (the ground pad 212PG) in the row R2 and the second GND pads (the ground pads 212PG) in the rows R4, R6 and R8.

As shown in FIG. 3, the third pads 212P3 in the rows R9 and R11 may be adjacent to the different third pads 212P3 in the row R10 along the direction 110. The first one, the third one and the fifth one of the CLK pads (the third pads 212P3) in the row R10 are located between the CLK pads (the third pads 212P3) in the row R9 and the GND pads (the ground pads 212PG) in the row R11. The second and fourth CLK pads (the third pads 212P3) in the row R10 are located between the GND pads (the ground pads 212PG) in the row R9 and the CLK pads (the third pads 212P3) in the row R11. It is note that the GND pad of the row R11 adjacent to the first GND pad of the row R10 may be replaced by other pads (e.g., the power pad).

In some embodiments, the arrangement of the GND pads (the ground pads 212PG) in the rows R2, R3, R4, R5, R6, R7, R8, R9, R10 and R11 can make sure the DQ pads (the second pads 212P2) in the rows R3, R4, R5, R6, R7 and R8 surrounded by GND pads (the ground pads 212PG).

In some embodiments, the electronic device may further include an additional row R12 of GND pads (the ground pads 212PG) beside the row R11 to make sure all the CLK pads (the third pads 212P3) in the row R11 surrounded by GND pads (the ground pads 212PG). For example, the row R12 may have least two GND pads (the ground pad 212PG) respectively adjacent to and aligned the two CLK pads (the third pads 212P3) in the row R11. the row R12 may have least two GND pads (the ground pad 212PG) respectively adjacent to and aligned the two CLK pads (the third pads 212P3) in the row R11.

In some embodiments, when the base 200 (FIG. 2) is a 10-layer printed circuit board, in which from the topmost conductive layer to the bottommost conductive layer may be respectively denoted as L1, L2, L3, L4, L5, L6, L7, L8, L9 and L10 in sequence. The conductive traces electrically connected to the CA pads (the first pads 212P1) may belong to the topmost conductive layer 204 (the first conductive layer L1) of the base 200. The conductive traces electrically connected to the DQ pads (the second pads 212P2) may belong to the third conductive layer (L3) of the base 200. The fifth conductive layer (L5) of the base 200 may include the conductive traces electrically connected to the CA pads (the first pad 212P1), the DQ pads (the second pads 212P2) and the CLK pads (the third pads 212P3). The seventh conductive layer (L7) and the ninth conductive layer (L9) of the base 200 may used for power transmission. In addition, the second conductive layer (L2), the fourth conductive layer (L4), the sixth conductive layer (L6), the eighth conductive layer (L8), and the bottommost conductive layer 206 (the tenth conductive layer L10) are designated as ground planes (GND planes).

Embodiments provide an electronic device. The electronic device includes a base and a semiconductor device. The semiconductor device is disposed on the top surface of the base. The semiconductor device has a device edge located within the base in a top view. The base has a unit pad array covered by the semiconductor device and electrically connected to the semiconductor device. The unit pad array includes a first pad region composed of a first row and a second row of the unit pad array. The first pad region includes first pads for transmitting commands and/or addresses to or from the semiconductor device. The first row of the unit pad array is arranged so that it is closer to the device edge than the second row of the unit pad array.

The unit pad array further includes a second pad region composed of a third row, a fourth row, a fifth row, a sixth row, a seventh row and an eighth row of the unit pad array. The second pad region includes second pads for transmitting data to or from the semiconductor device. The unit pad array further includes a third pad region composed of a ninth row, a tenth row and an eleventh row of the unit pad array. The third pad region includes third pads for transmitting clocks to or from the semiconductor device. The unit pad array further includes ground pads arranged in the first pad region, the second pad region and the third pad region except for the first row of the unit pad array.

In some embodiments, the first row of the unit pad array is composed of a portion of the first pads. In some embodiments, the second row of the unit pad array is composed of the remaining first pads and ground pads in the first pad region. In some embodiments, the remaining first pads are alternately arranged with the ground pads in the first pad region. In some embodiments, each of the ground pads in the first pad region is adjacent to the first pads in the first row and the second row of the unit pad array. In some embodiments, the first pads in the second row of the unit pad array are adjacent to the first pads in the first row of the unit pad array.

In some embodiments, the third to the eighth rows of the unit pad array are composed of the second pads and ground pads in the second pad region. In some embodiments, in each of the third to the eighth rows of the unit pad array, the second pads are alternately arranged with the ground pads. In some embodiments, the ground pads in the third row of the unit pad array are adjacent to the second pads and the first pads. In some embodiments, each of the second pads is adjacent to the ground pads in a row direction and a column direction.

In some embodiments, the ninth row to the eleventh row of the unit pad array are composed of the third pads and ground pads in the third pad region. In some embodiments, in the ninth row of the unit pad array, the third pads are alternately arranged with the ground pads. In some embodiments, the third pads in the ninth and eleventh rows are adjacent to the different third pads in the tenth row. In some embodiments, there are five third pads arranged side-by-side in the tenth row of the unit pad array. In some embodiments, the first one, the third one and the fifth one of the third pads in the tenth row are located between the third pads in the ninth row and the ground pads in the eleventh row. In some embodiments, the second and fourth third pads are located between the ground pads in the ninth row and the third pads in the eleventh row.

In some embodiments, the electronic device is designed to move CA pads of the base to the device edge of the semiconductor device (or the package edge of the semiconductor package) and fan out CA signals on topmost conductive layer (the first conductive layer L1) of the base. The electronic device may use pin multiplexing (pin mux) rule to match various structures on different DRAM chips, such as the DCD (data-address-data) structure, the DDC (data-data-address) structure or the CDD (address-data-data) structure without suffering the signal integrity (SI). According to the arrangement of CA pads, DQ pads, CLK pads and GND pads of the base, the pad array area can be shrunk, and the size (area) of the semiconductor device can be further reduced. In addition, the fabrication cost of the base is reduced.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a base having a top surface and a bottom surface; and
a semiconductor device disposed on the top surface of the base, wherein the semiconductor device has a device edge located within the base in a top view,
wherein the base has a unit pad array which is covered by the semiconductor device and electrically connected to the semiconductor device, wherein the unit pad array comprises:
a first pad region composed of a first row and a second row of the unit pad array, wherein the first pad region comprises:
first pads for transmitting commands and/or addresses to or from the semiconductor device,
wherein the first row of the unit pad array is arranged so that it is closer to the device edge than the second row of the unit pad array.

2. The electronic device as claimed in claim 1, wherein the unit pad array further comprises:
a second pad region composed of a third row, a fourth row, a fifth row, a sixth row, a seventh row and an eighth row of the unit pad array, wherein the second pad region comprises:
second pads for transmitting data to or from the semiconductor device.

3. The electronic device as claimed in claim 2, wherein the unit pad array further comprises:
a third pad region composed of a ninth row, a tenth row and an eleventh row of the unit pad array, wherein the third pad region comprises:
third pads for transmitting clocks to or from the semiconductor device.

4. The electronic device as claimed in claim 3, wherein the unit pad array further comprises:
ground pads arranged in the first pad region, the second pad region and the third pad region except for the first row of the unit pad array.

5. The electronic device as claimed in claim 1, wherein the first row of the unit pad array is composed of a portion of the first pads.

6. The electronic device as claimed in claim 5, wherein the second row of the unit pad array is composed of the remaining first pads and ground pads in the first pad region.

7. The electronic device as claimed in claim 6, wherein the remaining first pads are alternately arranged with the ground pads in the first pad region.

8. The electronic device as claimed in claim 6, wherein each of the ground pads in the first pad region is adjacent to the first pads in the first row and the second row of the unit pad array.

9. The electronic device as claimed in claim 1, wherein the first pads in the second row of the unit pad array are adjacent to the first pads in the first row of the unit pad array.

10. The electronic device as claimed in claim 2, wherein the third to the eighth rows of the unit pad array are composed of the second pads and ground pads in the second pad region.

11. The electronic device as claimed in claim 10, wherein in each of the third to the eighth rows of the unit pad array, the second pads are alternately arranged with the ground pads.

12. The electronic device as claimed in claim 10, wherein the ground pads in the third row of the unit pad array are adjacent to the second pads and the first pads.

13. The electronic device as claimed in claim 10, wherein each of the second pads is adjacent to the ground pads in a row direction and a column direction.

14. The electronic device as claimed in claim 3, wherein the ninth row to the eleventh row of the unit pad array are composed of the third pads and ground pads in the third pad region.

15. The electronic device as claimed in claim 14, wherein in the ninth and eleventh rows of the unit pad array, the third pads are alternately arranged with the ground pads.

16. The electronic device as claimed in claim 15, wherein the third pads in the ninth and eleventh rows are adjacent to the different third pads in the tenth row.

17. The electronic device as claimed in claim 16, wherein there are five third pads arranged side-by-side in the tenth row of the unit pad array.

18. The electronic device as claimed in claim 17, wherein the first one, the third one and the fifth one of the third pads in the tenth row are located between the third pads in the ninth row and the ground pads in the eleventh row.

19. The electronic device as claimed in claim 17, wherein the second and the fourth third pads are located between the ground pads in the ninth row and the third pads in the eleventh row.

20. An electronic device, comprising:
a base having a top surface and a bottom surface; and
a semiconductor device disposed on the top surface of the base, wherein the semiconductor device has a device edge located within the base in a top view,
wherein the base has a unit pad array which is covered by the semiconductor device and electrically connected to the semiconductor device, and the unit pad array comprises:
a first pad region composed of first pads and a first group of ground pads, wherein the first pads are configured to transmit commands and/or addresses to or from the semiconductor device;
a second pad region composed of second pads and a second group of ground pads, wherein the second pads are configured to transmit data to or from the semiconductor device; and
a third pad region composed of third pads and a third group of ground pads, wherein the third pads are configured to transmit clocks to or from the semiconductor device,
wherein the first pad region is arranged so that it is closer to the device edge than the second pad region, and the second pad region is arranged so that it is closer to the device edge than the third pad region.
